(19) United States
(12) Patent Application Publication
(10) Pub. No.: US 2016/0005659 A1
(43) Pub. Date: Jan. 7, 2016

(54) METHOD OF MANUFACTURING SEMICONDUCTOR DEVICE

(71) Applicant: SAMSUNG ELECTRONICS CO., LTD., Suwon-si (KR)

(72) Inventor: Hyun-Seung SONG, Incheon (KR)

(21) Appl. No.: 14/692,972

(22) Filed: Apr. 22, 2015

(30) Foreign Application Priority Data
Jul. 7, 2014 (KR) 10-2014-0084652

(51) Int. Cl. H01L 21/8234; H01L 21/027; H01L 21/768

(52) U.S. Cl. CPC H01L 21/823475; H01L 21/823418; H01L 21/76802; H01L 21/76877; H01L 21/0274

(57) ABSTRACT

Embodiments provide methods of manufacturing a semiconductor device. The method includes forming an interlayer insulating layer on a substrate; forming a plurality of contact holes penetrating the interlayer insulating layer, the plurality of contact holes arranged along a first direction and a second direction perpendicular to the first direction; and forming contacts in the contact holes, each contact hole being formed using a photo mask that is distinct from a photo mask used for forming a contact hole immediately adjacent to each contact hole in the first direction and distinct from a photo mask used for forming a contact hole immediately adjacent to each contact hole in the second direction, and top surfaces of the contacts being at a same level from the substrate.

### CROSS-REFERENCE TO RELATED APPLICATION

Korean Patent Application No. 10-2014-0084652, filed on Jul. 7, 2014, in the Korean Intellectual Property Office, and entitled: “Method of Manufacturing Semiconductor Device,” is incorporated by reference herein in its entirety.

### BACKGROUND

1. Field

Provided are methods of manufacturing a semiconductor device and, for example, to methods of manufacturing a semiconductor device including a plurality of logic cells.

2. Description of the Related Art

Semiconductor device may be used the electronic industry because of their small sizes, multi-functions, and low manufacture costs. Semiconductor devices may be categorized as semiconductor memory devices storing logical data, semiconductor logic devices processing logical data, and hybrid semiconductor devices having both the function of the semiconductor memory device and the function of the semiconductor logic device. Semiconductor devices with improved characteristics, for example, high-reliable, high-speed, and/or multi-functional semiconductor devices, have been increasingly demanded with the development of the electronic industry. As a result, structures of semiconductor devices have become more complex and semiconductor devices have become highly integrated.

### SUMMARY

Embodiments may be realized by providing a method of manufacturing a semiconductor device, the method including forming an interlayer insulating layer on a substrate; forming a plurality of contact holes penetrating the interlayer insulating layer, the plurality of contact holes arranged along a first direction and a second direction perpendicular to the first direction; and forming contacts in the contact holes, each contact hole being formed using a photo mask that is distinct from a photo mask used for forming a contact hole immediately adjacent to each contact hole in the first direction and distinct from a photo mask used for forming a contact hole immediately adjacent to each contact hole in the second direction, and top surfaces of the contacts being at a same level from the substrate.

The method may further include forming a plurality of active patterns extending in the first direction on the substrate; forming a plurality of gate structures intersecting the active patterns and extending in the second direction; and forming source/drain regions in the active patterns at both sides of each gate structure. The interlayer insulating layer may cover the active patterns, the gate structures, and the source/drain regions, and the contact holes may be arranged in the first direction with at least one of the gate structures therebetween and may be arranged along one sidewall of each gate structure in the second direction.

The contact holes may overlap with the source/drain regions when viewed from a plan view.

At least one of the contact holes may overlap with at least two source/drain regions that are spaced apart from each other in the second direction.

The contacts may be electrically connected to the source/drain regions.

At least one of the contacts may have a bar shape extending in the second direction and may electrically connect at least two source/drain regions, which are spaced apart from each other in the second direction, to each other.

The contact holes may expose the source/drain regions, and the contacts may be in contact with the source/drain regions.

The method may further include forming connecting conductive patterns, each of which connects the source/drain regions at each side of each gate structure to each other. The contact holes may expose top surfaces of the connecting conductive patterns, and the contacts may be electrically connected to the source/drain regions through the connecting conductive patterns.

The top surfaces of the contacts may be coplanar with a top surface of the interlayer insulating layer.

Forming the plurality of contact holes may include forming first contact holes using a first photo mask, the first contact holes penetrating the interlayer insulating layer; forming a first mask layer filling the first contact holes on the interlayer insulating layer; forming second contact holes using a second photo mask, the second contact holes penetrating the first mask layer and the interlayer insulating layer; forming a second mask layer filling the second contact holes on the first mask layer; and forming third contact holes using a third photo mask, the third contact holes penetrating the second mask layer, the first mask layer, and the interlayer insulating layer.

The method may further include forming gate structures on the substrate, the gate structures extending in the second directions and arranged in the first direction. The interlayer insulating layer may cover the gate structures, the first and second contact holes may be alternately and repeatedly arranged in the first direction, and the first and second contact holes adjacent to each other in the first direction may be spaced apart from each other with at least one of the gate structures therebetween.

The first and second contact holes may be alternately and repeatedly arranged in the second direction along one sidewall of at least one of the gate structures.

Each of the third contact holes may be spaced apart from at least one of the first contact holes or at least one of the second contact holes with at least one of the gate structures therebetween, and each of the third contact holes may be between one of the first contact holes and one of the second contact holes that is adjacent to the one of the first contact holes in the second direction.

Two contact holes immediately adjacent to each other in the first direction may be different two of the first, second, and third contact holes, and two contact holes immediately adjacent to each other in the second direction may be different two of the first, second, and third contact holes.

Each of the first contact holes may have a first width in the first direction, each of the second contact holes may have a second width in the first direction, each of the third contact holes may have a third width in the first direction, and the first width, the second width, and the third width may be equal to each other.

Embodiments may be realized by providing a method of manufacturing a semiconductor device, the method including forming a plurality of active patterns extending in a first direction on a substrate; forming a plurality of gate structures intersecting the active patterns and extending in a second direction intersecting the first direction; forming source/drain regions in the active patterns at both sides of each gate structure; forming an interlayer insulating layer covering the active patterns, the gate structures, and the source/drain regions on the substrate; and forming a plurality of contact holes penetrating the interlayer insulating layer, the plurality of contact holes arranged along the first direction and the second direction, the contact holes being arranged in the first direction with at least one of the gate structures therebetween and being arranged in the second direction along one sidewall of each gate structure, and each contact hole being formed using a photo mask that is distinct from a photo mask used for forming a contact hole immediately adjacent to each contact hole in the first direction and distinct from a photo mask used for forming a contact hole immediately adjacent to each contact hole in the second direction.

The contact holes may overlap with the source/drain regions when viewed from a plan view.

The method may further include forming contacts in the contact holes. Top surfaces of the contacts may be at a same level from the substrate.

The contacts may be electrically connected to the source/drain regions.

The method may further include forming connecting conductive patterns, each of which connects the source/drain regions at each side of each gate structure to each other. The contact holes may expose top surfaces of the connecting conductive patterns, and the contacts may be electrically connected to the source/drain regions through the connecting conductive patterns.

Embodiments may be realized by providing a method of manufacturing a semiconductor device, the method including forming an interlayer insulating layer on a substrate; and forming contact holes in the interlayer insulating layer using an exposure process, a distance between adjacent contact holes being smaller than a minimum pitch of the exposure process.

### BRIEF DESCRIPTION OF THE DRAWINGS

Features will become apparent to those of skill in the art by describing in detail exemplary embodiments with reference to the attached drawings in which:

FIGS. 1A to 5A illustrate plan views of stages in a method of manufacturing a semiconductor device according to some embodiments;

FIGS. 1B to 5B illustrate cross-sectional views taken along lines I-I′ of FIGS. 1A to 5A, respectively;

FIGS. 1C to 5C illustrate cross-sectional views taken along lines II-II′ of FIGS. 1A to 5A, respectively;

FIGS. 1D to 5D illustrate cross-sectional views taken along lines III-III′ of FIGS. 1A to 5A, respectively;

FIGS. 6A to 10A illustrate plan views of stages in a method of manufacturing a semiconductor device according to some embodiments;

FIGS. 6B to 10B illustrate cross-sectional views taken along lines I-I′ of FIGS. 6A to 10A, respectively;

FIGS. 6C to 10C illustrate cross-sectional views taken along lines II-II′ of FIGS. 6A to 10A, respectively;

FIGS. 6D to 10D illustrate cross-sectional views taken along lines III-III′ of FIGS. 6A to 10A, respectively; and

FIGS. 11 and 12 illustrate schematic block diagrams of electronic devices including semiconductor devices manufactured according to embodiments.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. The terminology used herein is for the purpose of describing particular embodiments only and is not intended to be limiting. As used herein, the singular terms “a,” “an” and “the” are intended to include the plural forms as well, unless, the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of embodiments. Accordingly, shapes of the exemplary views may be modified according to manufacturing techniques and/or allowable errors. Therefore, the embodiments are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the exemplary embodiments.

It will be also understood that although the terms first, second, third, etc., may be used herein to describe various elements, these elements should not be limited by these terms. These terms are only used to distinguish one element from another element. Thus, a first element in some embodiments could be termed a second element in other embodiments. Exemplary embodiments of aspects explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

Devices and methods of forming devices according to various embodiments described herein may be embodied in microelectronic devices such as integrated circuits, wherein a plurality of devices according to various embodiments described herein are integrated in the same microelectronic device. Accordingly, the cross-sectional view(s) illustrated herein may be replicated in two different directions, which need not be orthogonal, in the microelectronic device. Thus, a plan view of the microelectronic device that embodies devices according to various embodiments described herein may include a plurality of the devices in an array and/or in a two-dimensional pattern that is based on the functionality of the microelectronic device.

The devices according to various embodiments described herein may be interspersed among other devices depending on the functionality of the microelectronic device. Moreover, microelectronic devices according to various embodiments described herein may be replicated in a third direction that may be orthogonal to the two different directions, to provide three-dimensional integrated circuits.

Accordingly, the cross-sectional view(s) illustrated herein provide support for a plurality of devices according to various embodiments described herein that extend along two different directions in a plan view and/or in three different directions in a perspective view. For example, when a single active region is illustrated in a cross-sectional view of a device/structure, the device/structure may include a plurality of active regions and transistor structures (or memory cell structures, gate structures, etc., as appropriate to the case) thereon, as would be illustrated by a plan view of the device/structure.

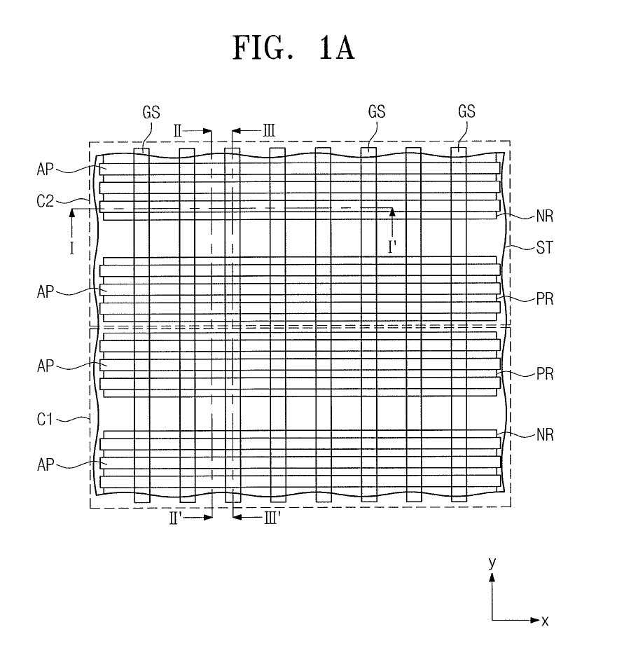

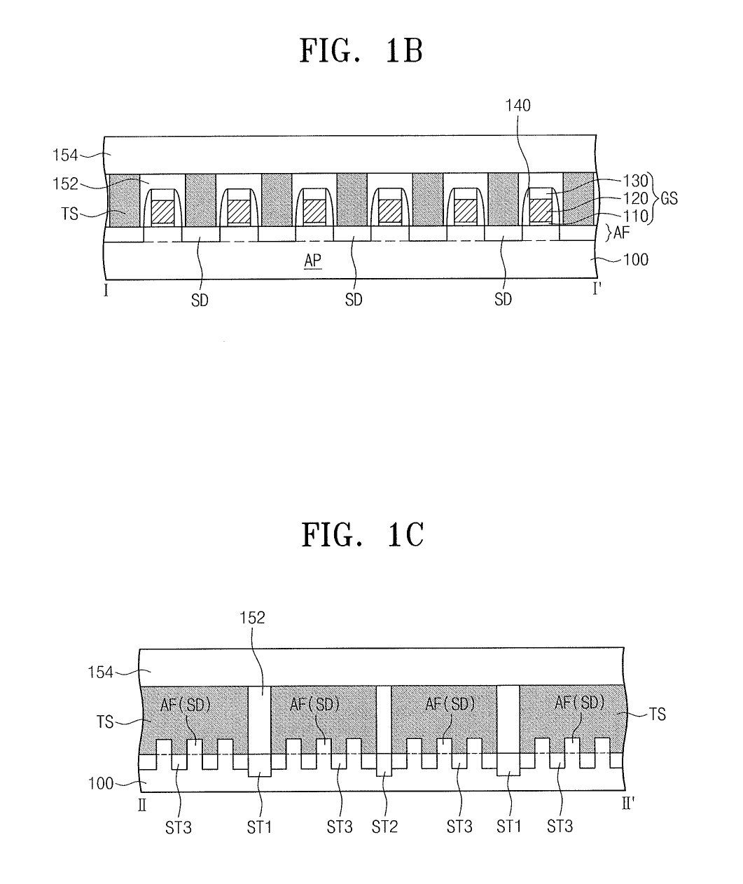

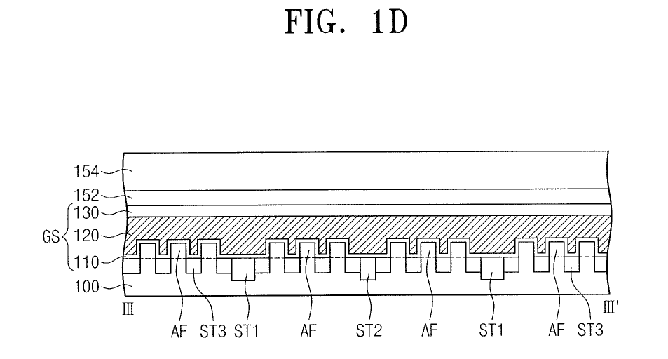

FIGS. 1A to 5A illustrate plan views of stages in a method of manufacturing a semiconductor device according to some embodiments. FIGS. 1B to 5B illustrate cross-sectional views taken along lines I-I′ of FIGS. 1A to 5A, respectively. FIGS. 1C to 5C illustrate cross-sectional views taken along lines II-II′ of FIGS. 1A to 5A, respectively. FIGS. 1D to 5D illustrate cross-sectional views taken along lines III-III′ of FIGS. 1A to 5A, respectively.

Referring to FIGS. 1A, 1B, 1C, and 1D, a device isolation layer ST may be formed in or on a substrate 100 to define active regions. The substrate 100 may be, for example, a silicon substrate, a germanium substrate, or a silicon-on-insulator (SOI) substrate. The device isolation layer ST may be formed by a shallow-trench isolation (STI) process and may include, for example, a silicon oxide layer. The active regions may include a P-type metal-oxide-semiconductor field effect transistor (PMOSFET) region PR and an N-type MOSFET (NMOSFET) region NR that are isolated from each other the device isolation layer ST.

A logic cell including the PMOSFET region PR and the NMOSFET region NR may be defined on the substrate 100. Hereinafter, the logic cell may be a unit for performing one logical operation in the present specification. For example, the logic cell may be configured to perform a storage function such as FLIP FLOP. The logic cell may be provided in plurality on the substrate 100. For example, the plurality of logic cells may include a first logic cell C1 and a second logic cell C2 that are spaced apart from each other in a y-direction. Each of the first logic cell C1 and the second logic cell C2 may include the PMOSFET region PR and the NMOSFET region NR which are isolated from each other by the device isolation layer ST. In an embodiment, the PMOSFET region PR and the NMOSFET region NR may be spaced apart from each other in the y-direction, and the PMOSFET region PR of the first logic cell C1 may be adjacent to the PMOSFET region PR of the second logic cell C2 in the y-direction.

The device isolation layer ST may include a first device isolation layer ST1 isolating the PMOSFET region PR and the NMOSFET region NR from each other and a second device isolation layer ST2 isolating the first logic cell C1 and the second logic cell C2 from each other. The first device isolation layer ST1 and the second device isolation layer ST1 may constitute one united body. The first and second device isolation layers ST1 and ST2 may be portions of one insulating layer, respectively.

According to an embodiment, the PMOSFET region PR and the NMOSFET region NR may be spaced apart from each other in the y-direction with the first device isolation layer ST1 therebetween. The first device isolation layer ST1 may extend in an x-direction to separate the PMOSFET region PR and the NMOSFET region NR from each other. Each of the PMOSFET region PR and the NMOSFET region NR may be illustrated as one region in FIG. 1A. In an embodiment, each of the PMOSFET region PR and the NMOSFET region NR may include a plurality of regions isolated by the first device isolation layer ST1. The second device isolation layer ST2 may extend in the x-direction to isolate the first and second logic cells C1 and C2 from each other.

The device isolation layer ST may further include a third device isolation layers ST3 that define active patterns AP on the PMOSFET region PR and the NMOSFET region NR. The third device isolation layer ST3 may extend in the x-direction, and active patterns AP may extend in the x-direction and may be spaced apart from each other in the y-direction. Each of the active patterns AP may have an upper portion (hereinafter, referred to as ‘an active fin AF’) that is exposed by the third device isolation layer ST3. The active patterns AP may be provided on the PMOSFET region PR and the NMOSFET region NR. In an embodiment, as illustrated in FIGS. 1A to 1D, three active patterns AP may be disposed on each of the active regions PR and NR.

Each of the first, second, and third device isolation layers ST1, ST2, and ST3 may have a depth in a direction perpendicular to a top surface of the substrate 100. In some embodiments, the depths of the third device isolation layers ST3 may be sallower than those of the first and second device isolation layers ST1 and ST2. The third device isolation layers ST3 may be formed by a process different from a process of forming the first and second device isolation layers ST1 and ST2. In other embodiments, the first, second, and third device isolation layer ST1, ST2, and ST3 may be formed at the same time, and the depths of the first, second, and third device isolation layers ST1, ST2, and ST3 may be substantially equal to each other.

Gate structures GS may be formed on the substrate 100 to intersect the active patterns AP. The gate structures GS may extend in the y-direction. The gate structures GS may be spaced apart from each other in the x-direction. Each of the gate structures GS may extend in the y-direction to intersect the PMOSFET region PR and the NMOSFET region NR. Each of the gate structures GS may include a gate dielectric pattern 110, a gate electrode 120, and a capping pattern 130 which are sequentially stacked. The gate dielectric pattern 110 may include at least one of a silicon oxide layer, a silicon oxynitride layer, or a high-k dielectric layer of which a dielectric constant is higher than that of a silicon oxide layer. The gate electrode 120 may include at least one of a doped semiconductor, a metal, or a conductive metal nitride. The capping pattern 130 may include at least one of a silicon oxide layer, a silicon nitride layer, or a silicon oxynitride layer.

A gate dielectric layer, a gate layer, and a capping layer may be sequentially formed on the substrate 100, and a patterning process may be performed on the capping layer, the gate layer, and the gate dielectric layer to form the gate dielectric pattern 110, the gate electrode 120, and the capping pattern 130. The gate dielectric layer, the gate layer, and the capping layer may be formed by a chemical vapor deposition (CVD) method and/or a sputtering method.

Gate spatters 140 may be formed on both sidewalls of each of the gate structures GS, respectively. A spacer layer may be formed on the substrate 100 to cover the gate structures GS, and the spacer layer may be anisotropically etched to form the gate spacers 140. The spacer layer may include at least one of a silicon oxide layer, a silicon nitride layer, or a silicon oxynitride layer.

Ion implantation processes may be performed on the substrate 100 having the gate structures GS to form source/drain regions SD. The source/drain regions SD may be formed in the active patterns AP at both sides of each gate structure GS. The source/drain regions SD may be confined in the active fins AF, as illustrated in FIG. 1B. In an embodiment, the source/drain regions SD may extend downwardly between the third device isolation layers ST3. The ion implantation processes may be performed using the gate structures as an ion implantation mask, and source/drain regions SD may not be formed in portions of the active patterns that are disposed under and overlap with the gate structures GS. The source/drain regions SD of the PMOSFET region PR doped with P-type dopants, and the source/drain regions SD of the NMOSFET region NR may be doped with N-type dopants.

A first interlayer insulating layer 152 covering the gate structures GS may be formed on the substrate 100. The first interlayer insulating layer 152 may include at least one of a silicon oxide layer and a silicon oxynitride layer.

Connecting conductive patterns TS may be formed to penetrate the first interlayer insulating layer 152 at both sides of each gate structure GS. The connecting conductive patterns TS may be connected to the source/drain regions SD. On the PMOSFET region PR, each of the connecting conductive patterns TS may electrically connect the source/drain regions SD, which are spaced apart from each other in the y-direction with the third device isolation layer ST3 therebetween, to each other. The connecting conductive patterns TS may be in direct contact with the source/drain regions SD. The source/drain regions SD of the NMOSFET region NR may be connected by the connecting conductive patterns TS by the same method as described above. On the NMOSFET region NR, each of the connecting conductive patterns TS may electrically connect the source/drain regions SD, which are spaced apart from each other in the y direction, to each other. Top surfaces of the connecting conductive patterns TS may be higher than top surfaces of the gate structures GS.

Forming the connecting conductive patterns TS may include patterning the first interlayer insulating layer 152 at both sides of each of the gate structures GS to form recess regions exposing the source/drain regions SD, forming a connecting conductive layer filling the recess regions on the first interlayer insulating layer 152, and planarizing the connecting conductive layer until the first interlayer insulating layer 152 is exposed.

The connecting conductive patterns TS may include a metal silicide. For example, the connecting conductive patterns TS may include at least one of titanium silicide, tantalum silicide, or tungsten silicide. The connecting conductive patterns TS may further include a metal layer. For example, the metal layer may include at least one of titanium, tantalum, or tungsten. In some embodiments, each of the connecting conductive patterns TS may include a metal silicide layer and a metal layer disposed on the metal silicide layer.

A second interlayer insulating layer 154 may be formed on the substrate 100 having the connecting conductive patterns TS. The second interlayer insulating layer 154 may include a silicon oxide layer or a silicon oxynitride layer.

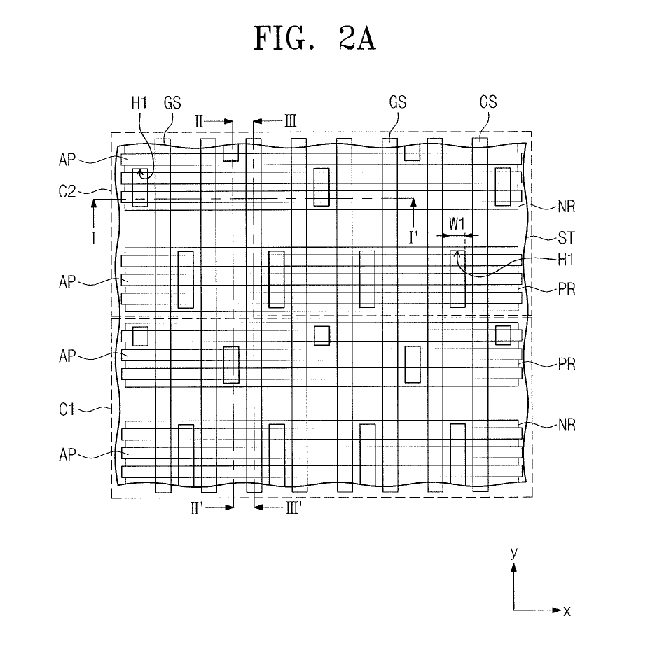

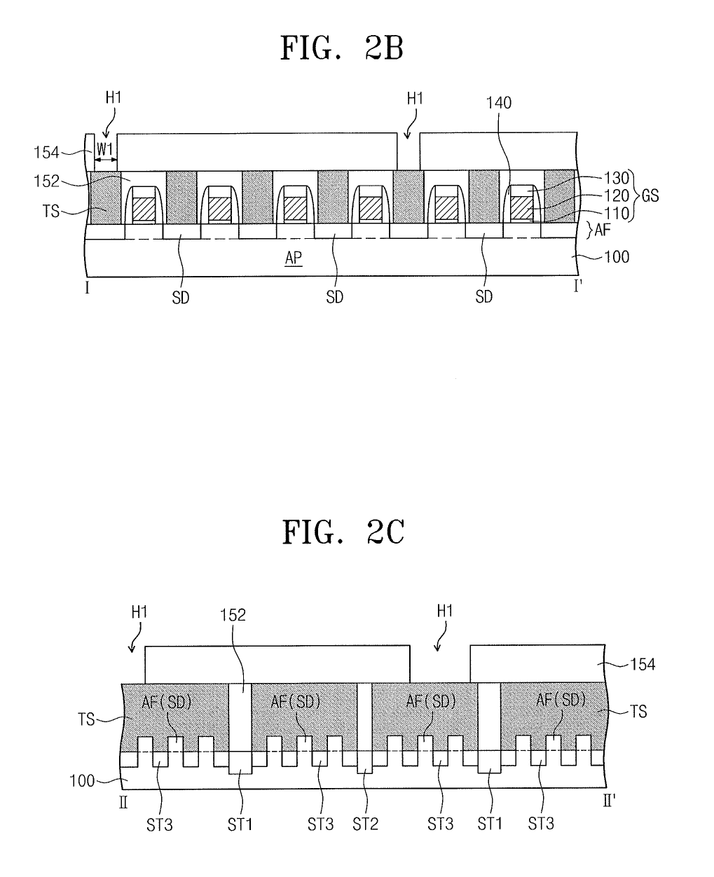

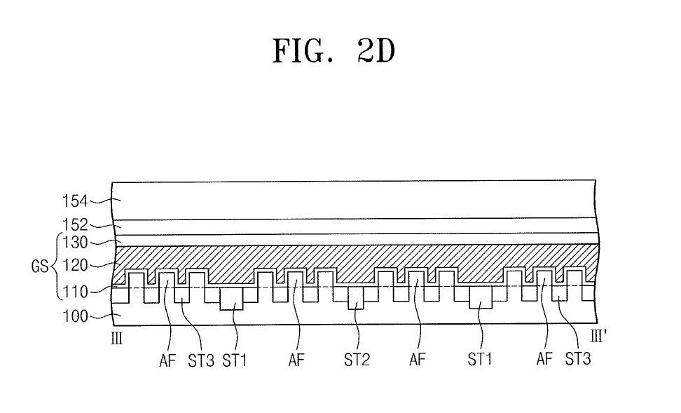

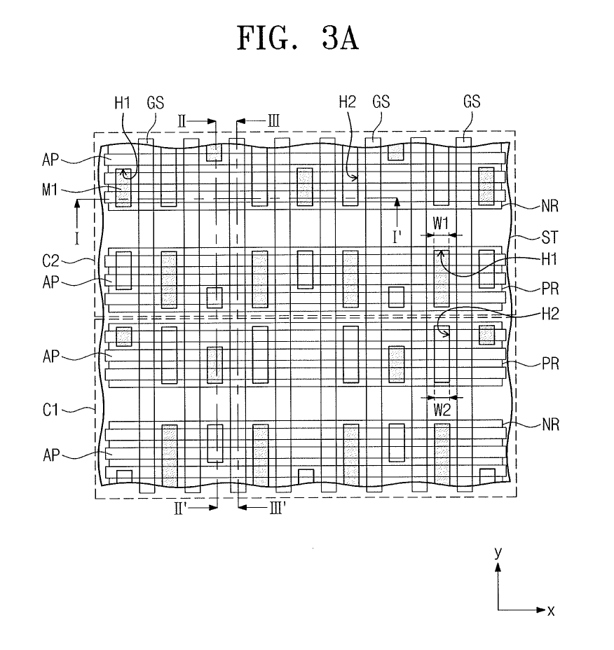

Referring to FIGS. 2A, 2B, 2C, and 2D, a first patterning process may be performed to form first contact holes H1 penetrating the second interlayer insulating layer 154. The first contact holes H1 may be disposed two-dimensionally on the substrate 100. The first contact holes H1 may be spaced apart from each other in the x-direction with at least two gate structures GS therebetween. The first contact holes H1 may be arranged in the y-direction along both sidewalls of each gate structure GS. The first contact holes H1 may be arranged in zigzag along both sidewalls of each gate structure GS.

The first patterning process may include forming a photoresist layer on the second interlayer insulating layer 154, performing a first exposure process using a first photo mask on the photoresist layer to form a photoresist pattern having openings defining the first contact holes H1, etching the second interlayer insulating layer 154 exposed by the openings, and removing the photoresist pattern.

According to some embodiments, the first contact holes H1 may expose the top surfaces of the connecting conductive patterns TS. At least one of the first contact holes H1 may extend along the top surface of the connecting conductive pattern TS. Each of the first contact holes H1 may have a first width W1 that corresponds to a distance between inner sidewalls of each of the first contact holes H1 in the x-direction.

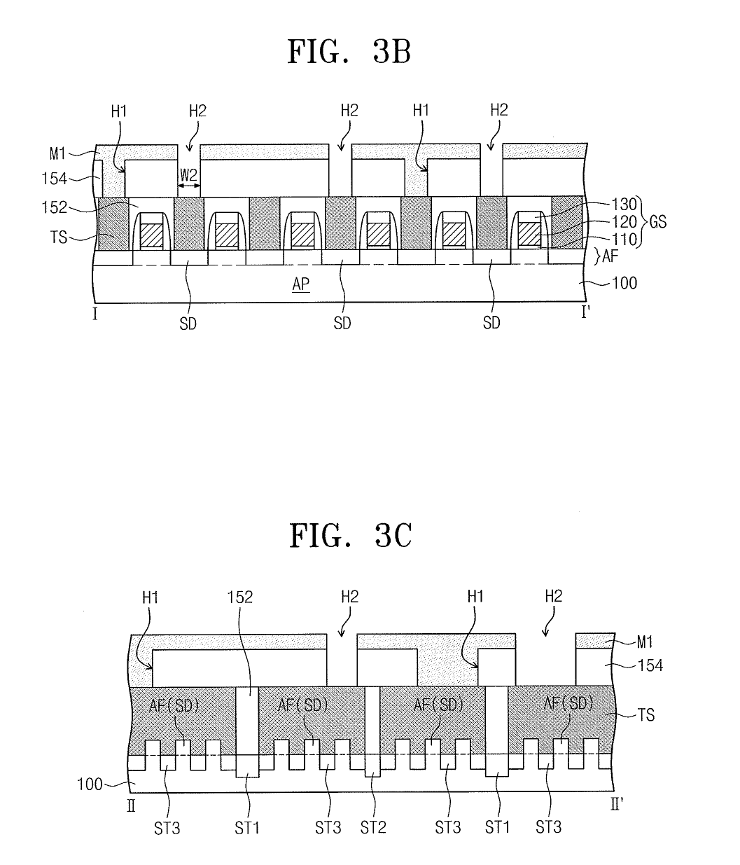

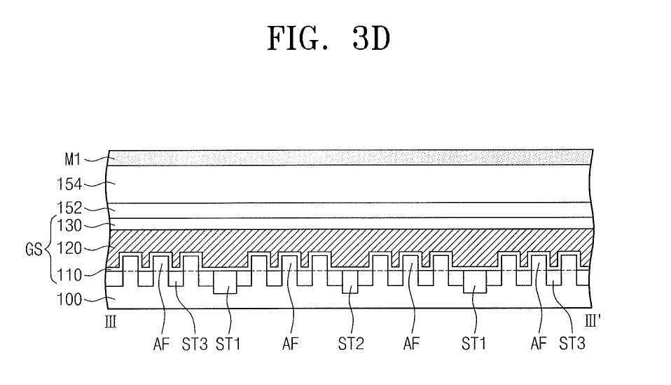

Referring to FIGS. 3A, 3B, 3C, and 3D, a first mask layer M1 filling the first contact holes H1 may be formed on the second interlayer insulating layer 154. The first mask layer M1 may be, for example, a spin-on-hardmask (SOH) layer.

A second patterning process may be performed to form second contact holes H2 penetrating the first mask layer M1 and the second interlayer insulating layer 154. The second contact holes H2 may be disposed two-dimensionally on the substrate 100. The second contact holes H2 may be spaced apart from each other in the x-direction with at least two gate structures GS therebetween. The second contact holes H2 may be arranged in the y-direction along both sidewalls of each gate structure GS. The second contact holes H2 may be arranged in zigzag along both sidewalls of each gate structure GS.

The second contact holes H2 may not overlap with the first contact holes H1. The first and second contact holes H1 and H2 may be alternately and repeatedly arranged in the x-direction. The first and second contact holes H1 and H2 adjacent to each other in the x-direction may be spaced apart from each other with at least one gate structure GS therebetween. The first and second contact holes H1 and H2 may be alternately and repeatedly arranged in the y-direction along one sidewall of each gate structure GS.

The second patterning process may include forming a photoresist layer on the first mask layer M1, performing a second exposure process using a second photo mask on the photoresist layer to form a photoresist pattern having openings defining the second contact holes H2, etching the first mask layer M1 and the second interlayer insulating layer 154 under the openings, and removing the photoresist pattern. The second photo mask may be distinct from the first photo mask. The first patterning process and the second patterning process may be performed independently of each other.

In some embodiments, the second contact holes H2 may expose the top surfaces of the connecting conductive patterns TS. At least one of the second contact holes H2 may extend along the top surface of the connecting conductive pattern TS. Each of the second contact holes H2 may have a second width that corresponds to a distance between inner sidewalls of each of the second contact holes H2 in the x-direction. In some embodiments, the first width W1 may be substantially equal to the second width W2.

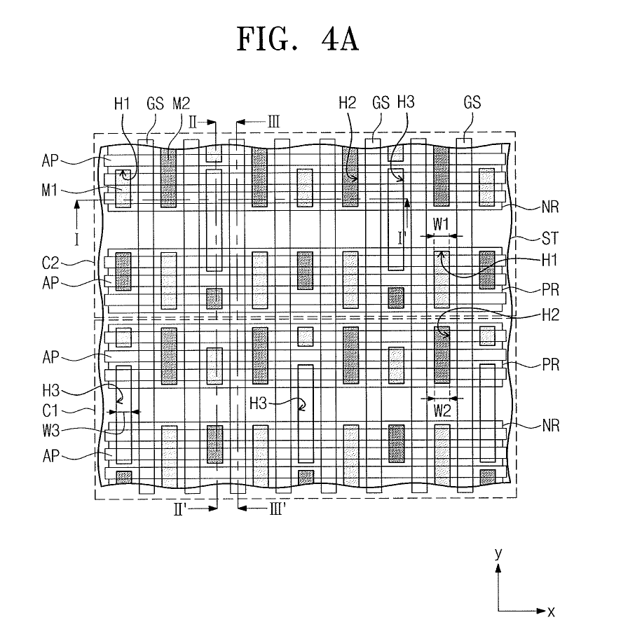

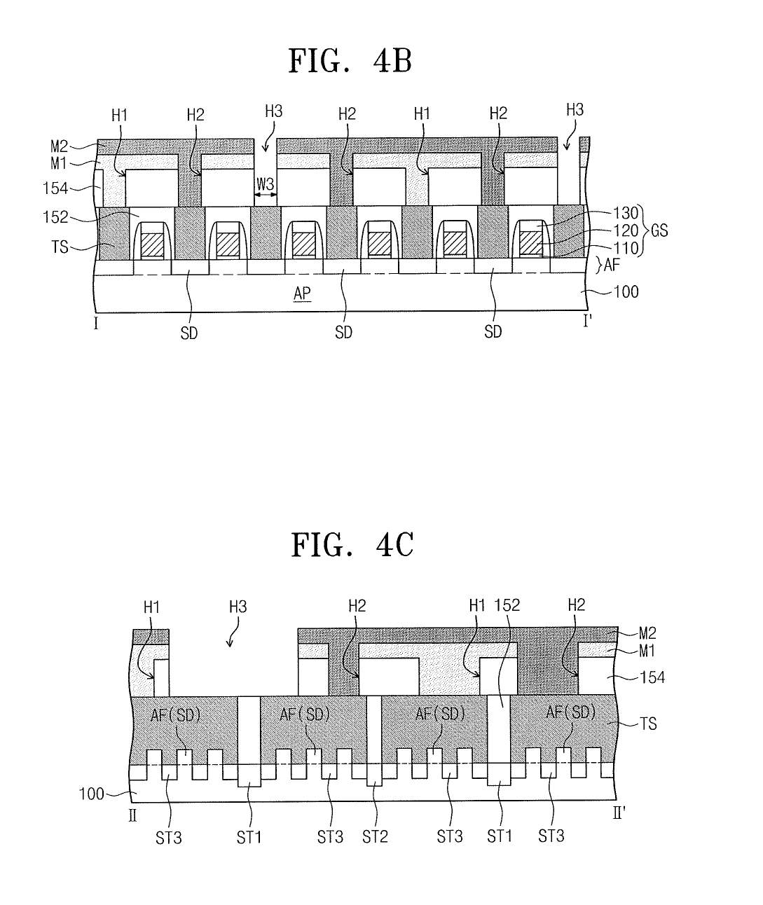

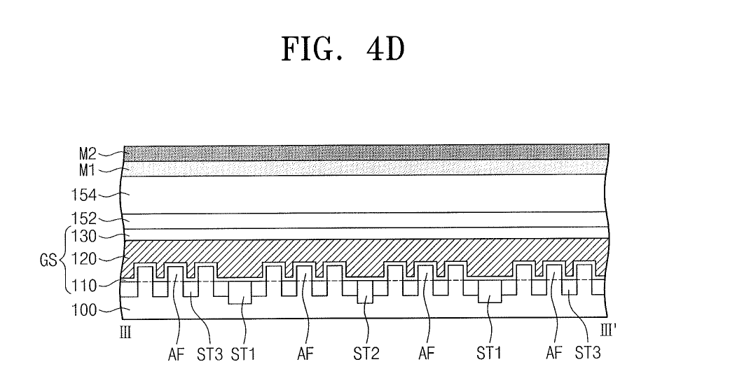

Referring to FIGS. 4A, 4B, 4C, and 4D, a second mask layer M2 filling the second contact holes H2 may be formed on the first mask layer Ml. The second mask layer M2 may be, for example, a SOH layer.

A third pattering process may be performed to form third contact holes H3 penetrating the second mask layer M2, the first mask layer M1, and the second interlayer insulating layer 154. The third contact holes H3 may be disposed two-dimensionally on the substrate 100. The third contact holes H3 may be spaced apart from each other in the x-direction with at least four gate structures GS therebetween. The third contact holes H3 may be arranged in zigzag along the y direction with at least two gate structures GS threrebetween. Each of the third contact holes H3 may extend in the y-direction along one sidewall of at least one gate structure GS. When viewed from a plan view, each of the third contact holes H3 may extend in the y-direction to overlap with the PMOSFET region PR and the NMOSFET region NR which are adjacent to each other.

The third contact holes H3 may not overlap with the first and second contact holes H1 and H2. Each of the third contact holes H3 may be spaced apart from at least one of the first contact holes H1 or at least one of the second contact holes H2 with at least one gate structure GS therebetween. Each of the third contact holes H3 may be disposed between the first contact hole H1 and the second contact hole H2 which are adjacent to each other in the y-direction.

The third patterning process may include forming a photoresist layer on the second mask layer M2, performing a third exposure process using a third photo mask on the photoresist layer to form a photoresist pattern having openings defining the third contact holes H3, etching the second mask layer M2, the first mask layer M1 and the second interlayer insulating layer 154 under the openings, and removing the photoresist pattern. The first photo mask, the second photo mask, and the third photo mask may be distinct from each other. The first patterning process, the second patterning process, and the third patterning process may be performed independently of each other.

According to some embodiments, each of the third contact holes H3 may expose the top surface of the connecting conductive pattern TS on the PMOSFET region PR, the top surface of the connecting conductive pattern TS on the NMOSFET region NR, and the top surface of the first interlayer insulating layer 152 on the first device isolation layer ST1. Each of the third contact holes H3 may have a third width W3 that corresponds to a distance between inner sidewalls of each of the third contact holes H3 in the x-direction. In some embodiments, the first, second, and third widths W1, W2, and W3 may be substantially equal to each other.

Two contact holes, immediately adjacent to each other in the x-direction, of the contact holes H1, H2, and H3 may be different two of the first, second, and third contact holes H1, H2, and H3. The two contact holes immediately adjacent to each other in the x-direction may be formed using the photo masks different from each other. Two contact hole, immediately adjacent to each other in the y-direction, of the contact holes H1, H2, and H3 may be different two of the first, second, and third contact holes H1, H2, and H3. The two contact holes immediately adjacent to each other in the y-direction may be formed using the photo masks different from each other.

If adjacent contact holes are formed using a single photo mask at the same time, a minimum pitch of the adjacent contact holes may be determined depending on a limit of the resolution of an exposure process. As integration degrees of semiconductor devices increase, a distance between the adjacent contact holes may become smaller than the minimum pitch, and it may be difficult to form the adjacent contact holes using the same photo mask. If contact holes disposed at the same level from a substrate are formed using a plurality of photo masks, a manufacture cost of a semiconductor device may increase.

According to embodiments, the two contact holes immediately adjacent to each other in the x-direction may be formed using the patterning processes different from each other (i.e., using the photo masks different from each other), and the two contact holes immediately adjacent to each other in the y-direction may also be formed using the patterning processes different from each other (i.e., using the photo masks different from each other). Thus, even though a distance between two adjacent contact holes may be smaller than the minimum pitch, the contact holes may be easily formed regardless of the limit of the resolution of the exposure process. Since the contact holes adjacent to each other in the x-direction and the y-direction are formed using the patterning processes different from each other (i.e., using the photo masks different from each other), it may be possible to provide the method of manufacturing the highly integrated semiconductor device. The number of the photo masks used for the contact holes adjacent to each other in the x-direction and y-direction may be reduced or minimized to minimize the manufacture cost of the semiconductor device.

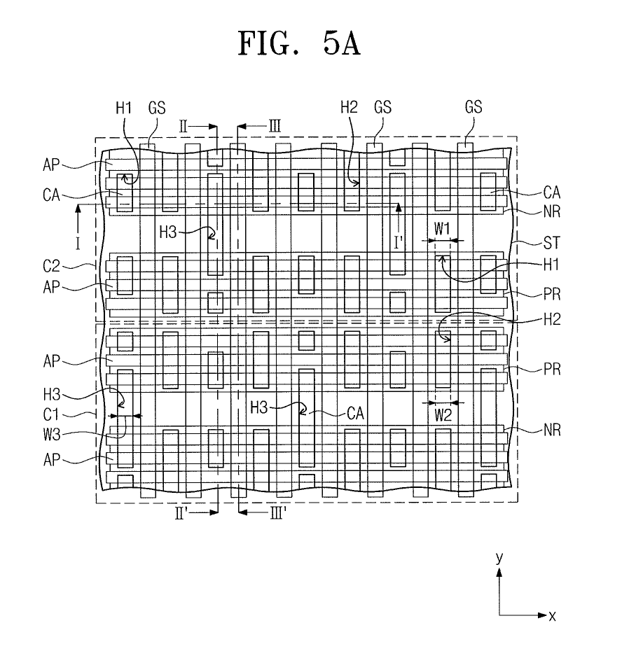

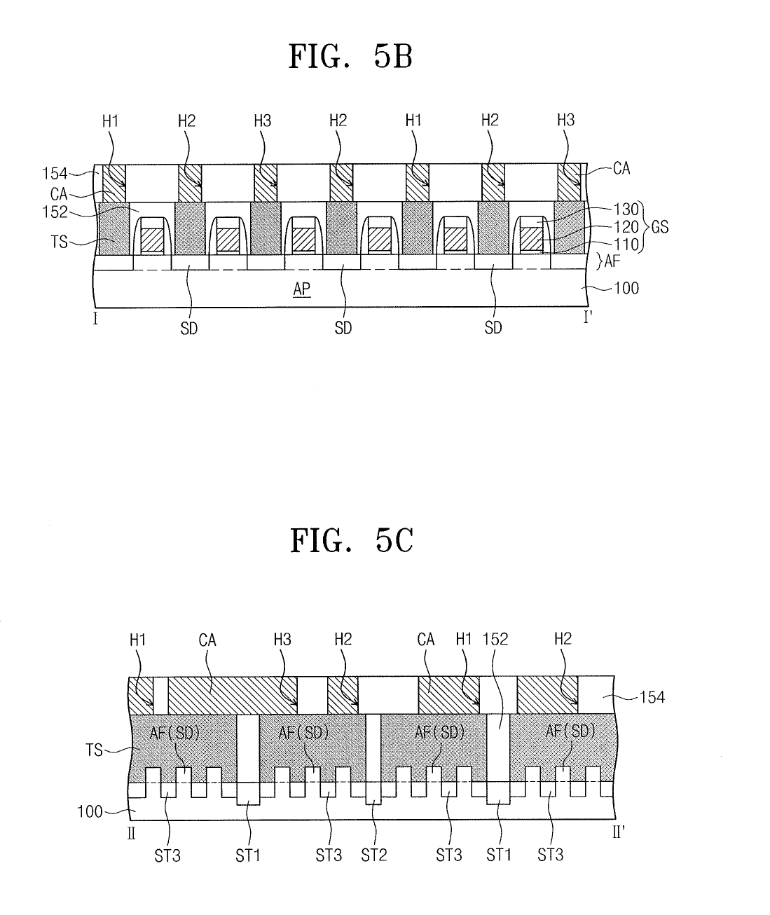

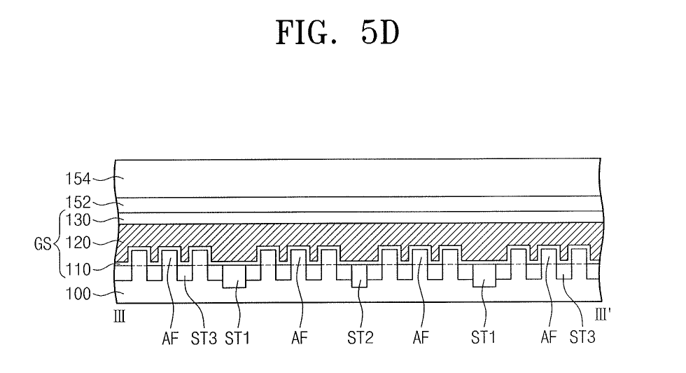

Referring to FIGS. 5A, 5B, SC, and SD, the first and second mask layers M1 and M2 may be removed. The first and second mask layers M1 and M2 may be removed by performing an ashing process and/or a strip process. Subsequently, a conductive layer filling the contact holes H1, H2, and H3 may be formed on the second interlayer insulating layer 154. The conductive layer may include at least one of a doped semiconductor, a metal, or a conductive metal nitride. The conductive layer may be planarized until the second interlayer insulating layer 154 is exposed, thereby forming contacts CA that are locally provided in the contact holes H1, H2, and H3, respectively. Top surfaces of the contacts CA may be substantially coplanar with the top surface of the second interlayer insulating layer 154 by the planarization process performed on the conductive layer.

The contacts CA may be electrically connected to the source/drain regions SD disposed at both sides of each gate structure GS through the connecting conductive patterns TS. In some embodiments, the contacts CA may include at least one contact that has a bar shape extending in the y-direction. The contacts CA may include at least one contact that extends onto the device isolation layer ST to electrically connect the source/drain region SD of the PMOSFET region PR to the source/drain region SD of the NMOSFET region NR. Top surfaces of the contacts CA may be disposed at a substantially same level from the top surface of the substrate 100.

Gate contacts that are electrically connected to the gate electrodes 120 may be formed on the gate structures GS. Top surfaces of the gate contacts and the top surfaces of the contacts CA may be disposed at a substantially same level from the top surface of the substrate 100. The gate contacts may include the same material as the contacts CA. Interconnections may be provided on the substrate 100 so as to be electrically connected to the contacts CA and the gate contacts. The interconnections may apply voltages to the source/drain regions SD and the gate electrodes 120 through the contacts CA and the gate contacts.

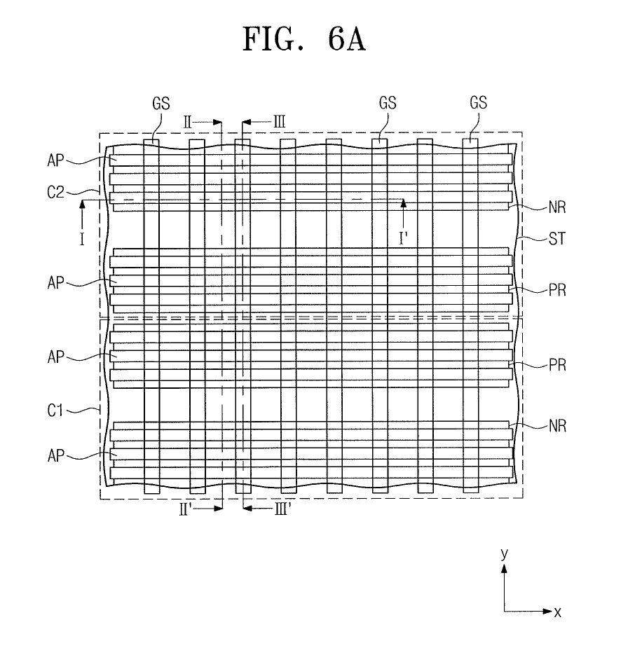

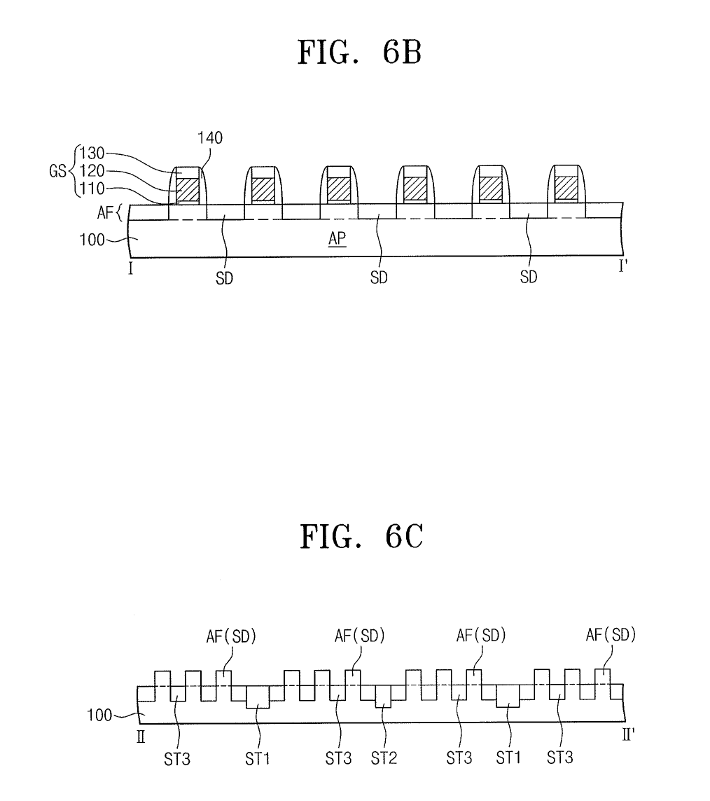

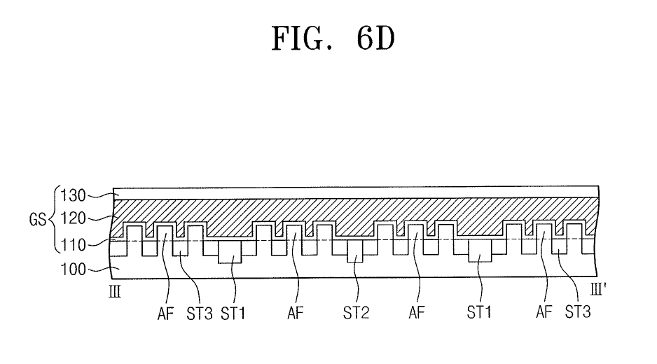

FIGS. 6A to 10A illustrate plan views of stages in a method of manufacturing a semiconductor device according to some embodiments. FIGS. 6B to 10B illustrate cross-sectional views taken along lines I-I′ of FIGS. 6A to 10A, respectively. FIGS. 6C to 10C illustrate cross-sectional views taken along lines II-II′ of FIGS. 6A to 10A, respectively. FIGS. 6D to 10D illustrate cross-sectional views taken along lines of FIGS. 6A to 10A, respectively. Hereinafter, the same elements as described with reference to FIGS. 1A to 5A, 1B to 5B, 1C to 5C, and 1D to 5D will be indicated by the same reference numerals or the same reference designators, and the descriptions thereto will be omitted or mentioned briefly for the purpose of ease and convenience in explanation.

Referring to FIGS. 6A, 6B, 6C, and 6D, a device isolation layer ST may be formed in or on a substrate 100 to define active regions. The active regions may include a PMOSFET region PR and an NMOSFET region NR that are isolated from each other the device isolation layer ST. The device isolation layer ST may include a third device isolation layers ST3 that define active patterns AP on the PMOSFET region PR and the NMOSFET region NR. The third device isolation layer ST3 may extend in an x-direction, and active patterns AP may extend in the x-direction and may be spaced apart from each other in a y-direction. Each of the active patterns AP may have an upper portion (hereinafter, referred to as ‘an active fin AF’) that is exposed by the third device isolation layer ST3. The active patterns AP may be provided on the PMOSFET region PR and the NMOSFET region NR.

Gate structures GS may be formed on the substrate 100 to intersect the active patterns AP. The gate structures GS may extend in the y-direction. Each of the gate structures GS may include a gate dielectric pattern 110, a gate electrode 120, and a capping pattern 130 which are sequentially stacked. Gate spatters 140 may be formed on both sidewalls of each of the gate structures GS, respectively.

Ion implantation processes may be performed on the substrate 100 having the gate structures GS to form source/drain regions SD. The source/drain regions SD may be formed in the active patterns AP at both sides of each gate structure GS.

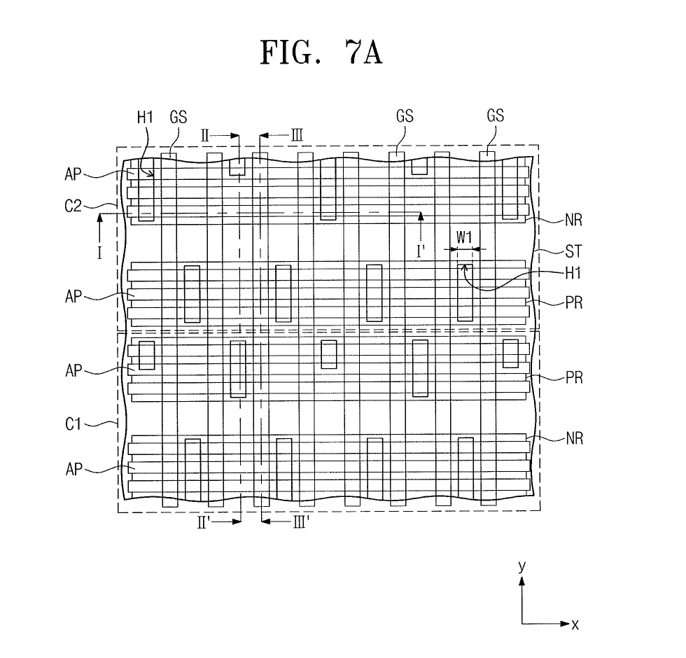

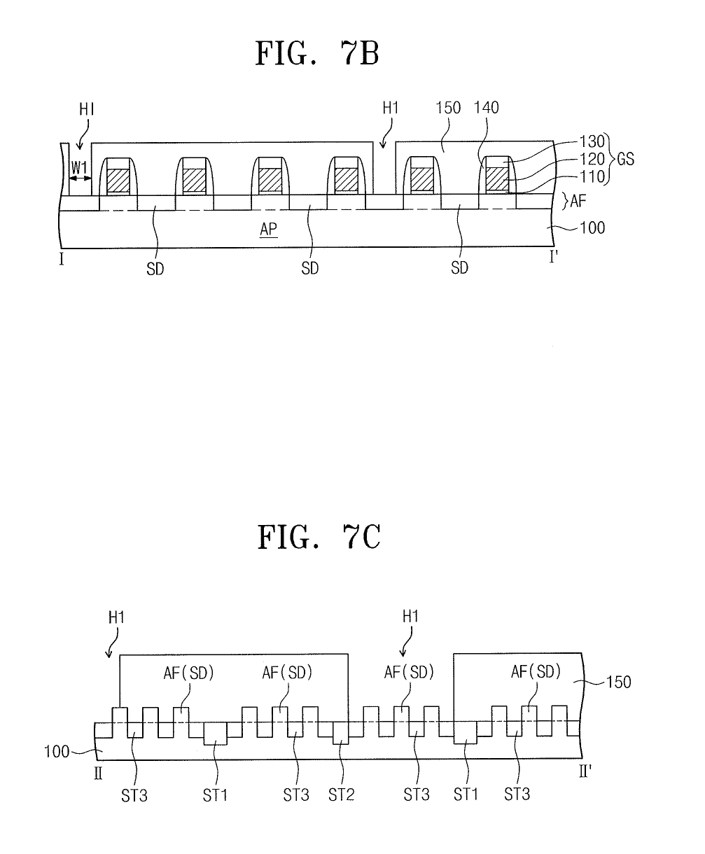

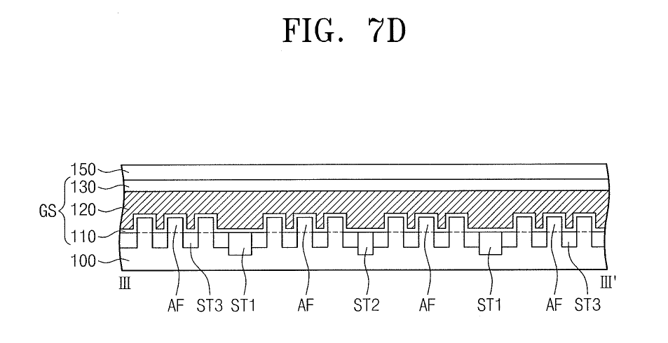

Referring to FIGS. 7A, 7B, 7C, and 7D, an interlayer insulating layer 150 may be formed on the substrate 100 to cover the gate structures GS. The interlayer insulating layer 150 may include at least one of a silicon oxide layer and a silicon oxynitride layer.

A first patterning process may be performed to form first contact holes H1 penetrating the interlayer insulating layer 150. The first contact holes H1 may be disposed two-dimensionally on the substrate 100. The first contact holes H1 may be spaced apart from each other in the x-direction with at least two gate structures GS therebetween. The first contact holes H1 may be arranged in the y-direction along both sidewalls of each gate structure GS. The first contact holes H1 may be arranged in zigzag along both sidewalls of each gate structure GS. The first patterning process may be the substantially same as described with reference to FIGS. 2A to 2D.

According to the present embodiment, the first contact holes H1 may expose the source/drain regions SD. At least one of the first contact holes H1 may extend in the y-direction to expose the source/drain regions SD which are spaced apart from each other in the y-direction. Each of the first contact holes H1 may have a first width W1 in the x-direction.

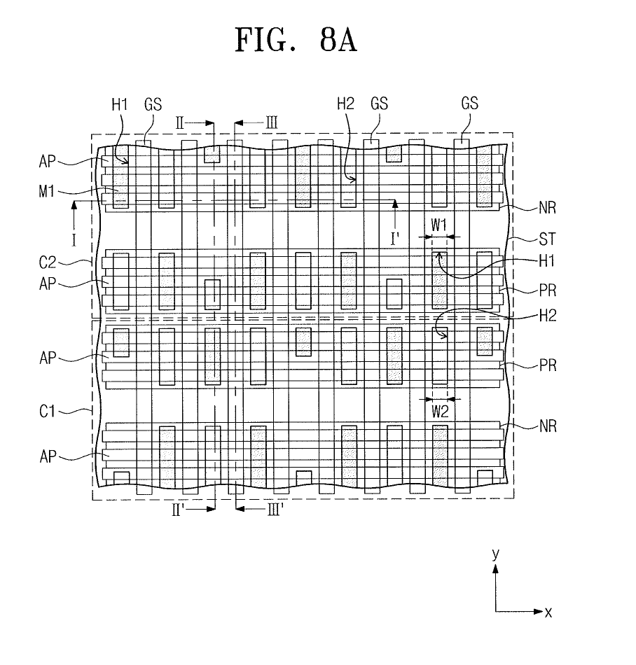

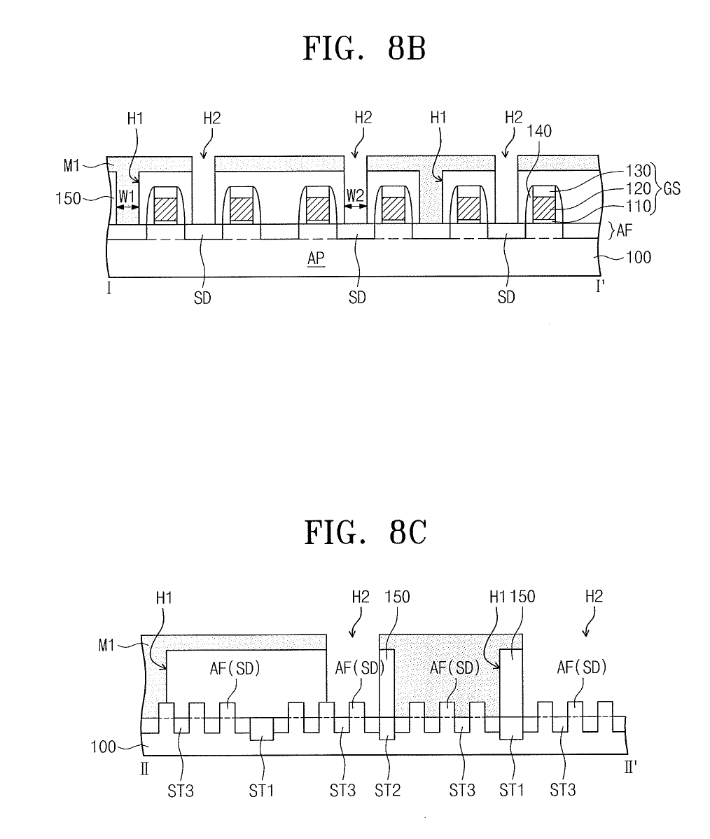

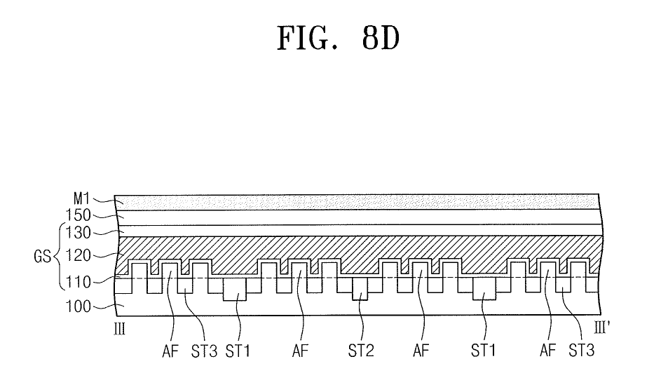

Referring to FIGS. 8A, 8B, 8C, and 8D, a first mask layer M1 filling the first contact holes H1 may be formed on the interlayer insulating layer 150. A second patterning process may be performed to form second contact holes H2 penetrating the first mask layer M1 and the interlayer insulating layer 150. The second contact holes H2 may be disposed two-dimensionally on the substrate 100. The second contact holes H2 may be spaced apart from each other in the x-direction with at least two gate structure GS therebetween. The second contact holes H2 may be arranged in the y-direction along both sidewalls of each gate structure GS. The second contact holes H2 may be arranged in zigzag along both sidewalls of each gate structure GS

The second contact holes H2 may not overlap with the first contact holes H1. The first and second contact holes H1 and H2 may be alternately and repeatedly arranged in the x-direction. The first and second contact holes H1 and H2 adjacent to each other in the x-direction may be spaced apart from each other with at least one gate structure GS therebetween. The first and second contact holes H1 and H2 may be alternately and repeatedly arranged in the y-direction along one sidewall of each gate structure GS.

The second patterning process may be the substantially same as described with reference to FIGS. 3A to 3D.

According to the present embodiment, the second contact holes H2 may expose the source/drain regions SD. At least one of the second contact holes H2 may extend in the y-direction to expose the source/drain regions SD which are spaced apart from each other in the y-direction. Each of the second contact holes H2 may have a second width W2 in the x-direction. The first width W1 may be substantially equal to the second width W2.

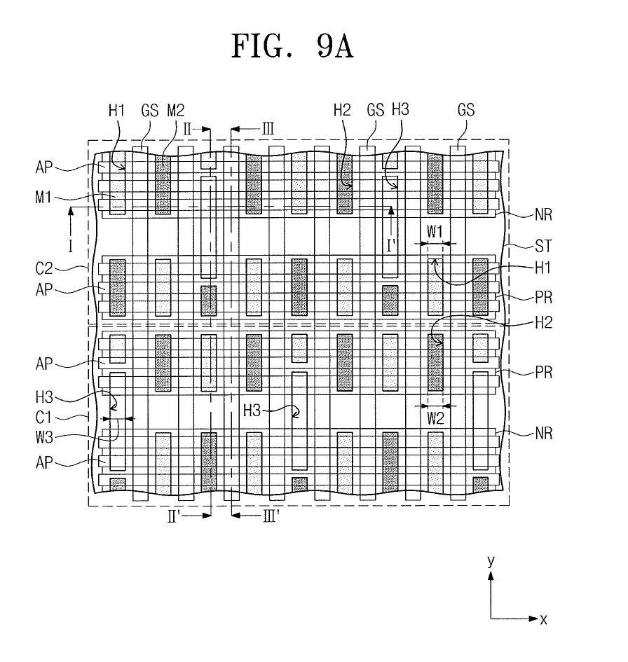

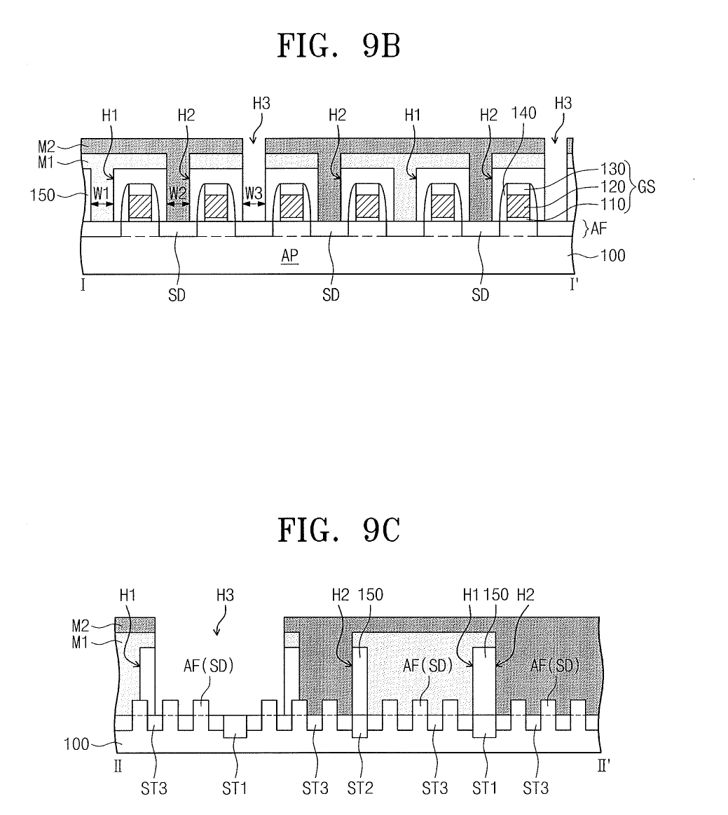

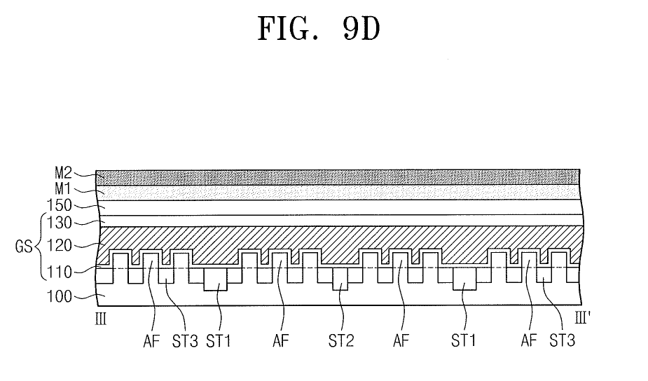

Referring to FIGS. 9A, 9B, 9C, and 9D, a second mask layer M2 filling the second contact holes H2 may be formed on the first mask layer Ml. A third pattering process may be performed to form third contact holes H3 penetrating the second mask layer M2, the first mask layer M1, and the interlayer insulating layer 150. The third contact holes H3 may be disposed two-dimensionally on the substrate 100. The third contact holes H3 may be spaced apart from each other in the x-direction with at least four gate structures GS therebetween. The third contact holes H3 may be arranged in zigzag along the y direction with at least two gate structures GS threrebetween. Each of the third contact holes H3 may extend along one sidewall of at least one gate structure GS in the y-direction. When viewed from a plan view, each of the third contact holes H3 may extend in the y-direction to overlap with the PMOSFET region PR and the NMOSFET region NR which are adjacent to each other.

The third contact holes H3 may not overlap with the first and second contact holes H1 and H2. Each of the third contact holes H3 may be spaced apart from at least one of the first contact holes H1 or at least one of the second contact holes H2 with at least one gate structure GS therebetween. Each of the third contact holes H3 may be disposed between one of the first contact holes H1 and one of the second contact hole H2 which is adjacent to the one of the first contact holes H1 in the y-direction.

The third patterning process may be the substantially same as described with reference to FIGS. 4A to 4D.

According to the present embodiment, each of the third contact holes H3 may expose the source/drain region SD of the PMOSFET region PR, the source/drain region SD of the NMOSFET region NR, and the first device isolation layer ST1 isolating the PMOSFET and NMOSFET regions PR and NR from each other. Each of the third contact holes H3 may have a third width W3 in the x-direction. The first, second, and third widths W1, W2, and W3 may be substantially equal to each other.

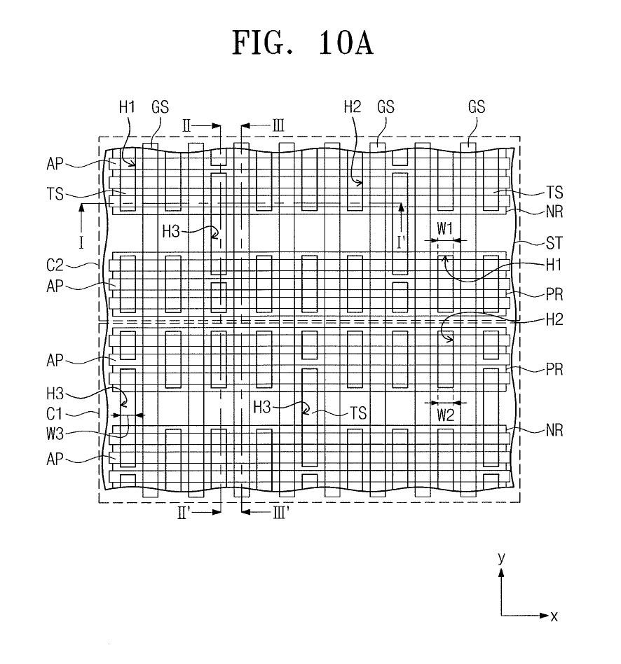

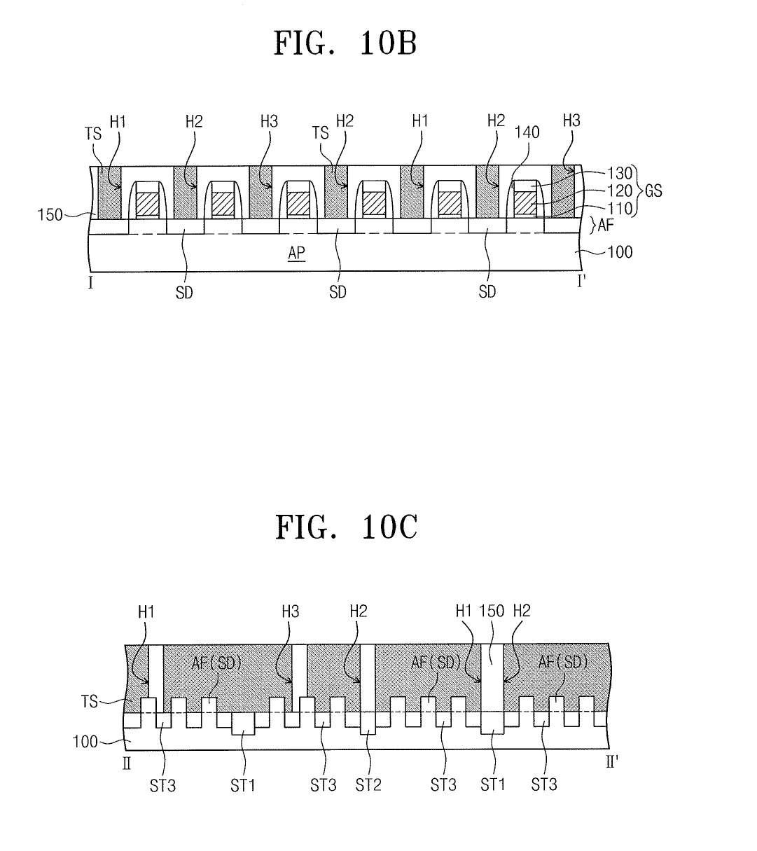

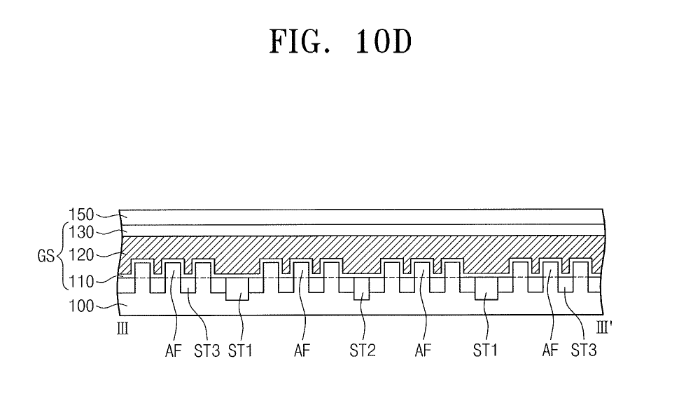

Referring to FIGS. 10A, 10B, 10C, and 10D, the first and second mask layers M1 and M2 may be removed. Subsequently, a connecting conductive layer filling the contact holes H1, H2, and H3 may be formed on the interlayer insulating layer 150. The connecting conductive layer may include a metal silicide layer. For example, the connecting conductive layer may include at least one of titanium silicide, tantalum silicide, or tungsten silicide. The connecting conductive layer may further include a metal layer. For example, the metal layer may include at least one of titanium, tantalum, or tungsten. In some embodiments, the connecting conductive layer may include the metal silicide layer and the metal layer disposed on the metal silicide layer. The connecting conductive layer may be planarized until the interlayer insulating layer 150 is exposed, thereby forming connecting conductive patterns TS that are locally provided in the contact holes H1, H2, and H3, respectively. Top surfaces of the connecting conductive patterns TS may be substantially coplanar with a top surface of the interlayer insulating layer 150 by the planarization process performed on the connecting conductive layer. The connecting conductive patterns TS formed in the contact holes H1, H2, and H3 may correspond to contacts that are in contact with the source/drain regions S/D.

On the PMOSFET region PR, each of some of the connecting conductive patterns TS may electrically connect the source/drain regions SD, which are spaced apart from each other in the y-direction with the third device isolation layer ST3 therebetween, to each other. The connecting conductive patterns TS may be in direct contact with the source/drain regions SD. The source/drain regions SD of the NMOSFET region NR may be connected by the connecting conductive patterns TS by the same method as described above. On the NMOSFET region NR, each of some of the connecting conductive patterns TS may electrically connect the source/drain regions SD, which are spaced apart from each other in the y direction, to each other. According to the present embodiment, each of others of the connecting conductive patterns TS may extend onto the second device isolation layer ST2 to electrically connect the source/drain region SD of the PMOSFET region PR to the source/drain region SD of the NMOSFET region NR. Each of others of the connecting conductive patterns TS may be in direct contact with the top surface of the second device isolation layer ST2, the source/drain region SD of the PMOSFET region PR, and the source/drain regions of the NMOSFET region NR. Additional contacts for connecting the source/drain regions SD of the PMOSFET region PR to the source/drain regions SD of the NMOSFET region NR may not be required. Top surfaces of the connecting conductive patterns TS may be higher than top surfaces of the gate structures GS.

Gate contacts that are electrically connected to the gate electrodes 120 may be formed on the gate structures GS. Interconnections may be provided on the substrate 100 so as to be electrically connected to the connecting conductive patterns TS and the gate contacts.

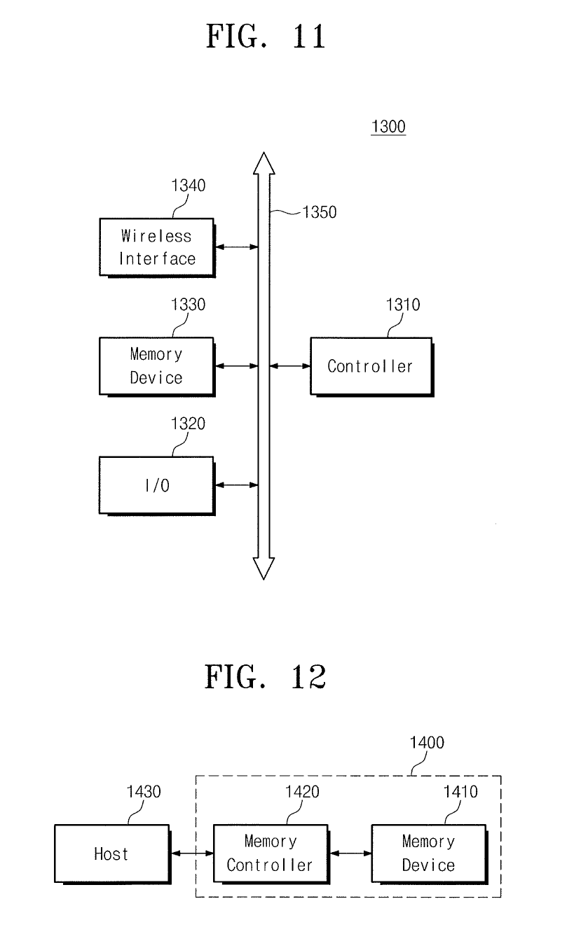

FIGS. 11 and 12 illustrate schematic block diagrams of electronic devices including semiconductor devices manufactured according to embodiments.

Referring to FIG. 11, an electronic device 1300 including the semiconductor device according to embodiments may be one of a personal digital assistant (PDA), a laptop computer, a portable computer, a web tablet, a wireless phone, a mobile phone, a digital music player, a cable/wireless electronic device, or a composite electronic device including at least two thereof. The electronic device 1300 may include a controller 1310, an input/output (I/O) unit 1320 (e.g., a keypad, a keyboard, or a display), a memory device 1330, and a wireless interface unit 1340 which are coupled to each other through a data bus 1350. For example, the controller 1310 may include at least one of a microprocessor, a digital signal processor, a microcontroller, or another logic device having a similar function to one thereof. The memory device 1330 may store, for example, commands executed through the controller 1310. Additionally, the memory device 1330 may store user's data. The memory device 1330 may include at least one of the semiconductor devices in the aforementioned embodiments. The electronic device 1300 may transmit data to a wireless communication network using a radio frequency (RF) signal or receive data from the network by the wireless interface unit 1340. For example, the wireless interface unit 1340 may include antenna or a wireless transceiver. The electronic device 1300 may be used to realize a communication interface protocol of a communication system such as CDMA, GSM, NADC, E-TDMA, WCDMA, CDMA2000, Wi-Fi, Muni Wi-Fi, Bluetooth, DECT, Wireless USB, Flash-OFDM, IEEE 802.20, GPRS, iBurst, WiBro, WiMAX, WiMAX-Advanced, UMTS-TDD, HSPA, EVDO, LTE-Advanced, or MMDS.

Referring to FIG. 12, the semiconductor devices according to embodiments may be used to realize a memory system. A memory system 1400 may include a memory device 1410 and a memory controller 1420 for storing massive data. The memory controller 1420 may control the memory device 1410 to read/write data from/into the memory device 1410 in response to read/write request of a host 1430. The memory controller 1420 may make an address mapping table for mapping an address provided from the host 1430 (e.g., a mobile device or a computer system) into a physical address of the memory device 1410. The memory device 1410 may include at least one of the semiconductor devices according to the above embodiments.

The semiconductor devices described in the aforementioned embodiments may be encapsulated using various packaging techniques. For example, the semiconductor devices according to the aforementioned embodiments may be encapsulated using one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic metric quad flat package (PMQFP) technique, a plastic quad flat package (PQFP) technique, a small outline package (SOC) technique, a shrink small outline package (SSOP) technique, a thin small outline package (TSOP) technique, a thin quad flat package (TQFP) technique, a system in package (SIP) technique, a multi-chip package (MCP) technique, a wafer-level fabricated package (WFP) technique and a wafer-level processed stack package (WSP) technique.

The package in which the semiconductor device according to one of the above embodiments is mounted may further include at least one semiconductor device (e.g., a controller and/or a logic device) that controls the semiconductor device.

According to embodiments, the two contact holes immediately adjacent to each other in the x-direction may be formed using the patterning processes different (or distinct) from each other (i.e., the photo masks different (or distinct) from each other), and the two contact holes immediately adjacent to each other in the y-direction may be formed using the patterning process different (or distinct) from each other (i.e., the photo masks different (or distinct) from each other). Thus, even though the distance between adjacent contact holes may smaller than the minimum pitch of the exposure process, i.e., a minimum distance between features achievable by the exposure process based on a limit of resolution of the exposure process, the contact holes may be easily formed regardless of the limit of the resolution of the exposure process. It may be possible to provide the method of manufacturing the highly integrated semiconductor device.

The number of the photo masks used for the contact holes adjacent to each other in the x and y-directions may be reduced or minimized to minimize the manufacture cost of the semiconductor device.

By way of summation and review, when contacts connected to source/drain regions are formed in a SRAM cell, they may be formed using a plurality of photo masks because of a limit of the resolution of a photolithography process. Two contacts immediately adjacent to each other in an x-direction may be formed using different photo masks from each other, but two contacts immediately adjacent to each other in a y-direction may be formed using the same photo mask. If two contacts immediately adjacent to each other the y-direction are formed using the same photo mask, a bridge may occur between the two contacts immediately adjacent to each other the y-direction.

Embodiments may provide methods of manufacturing a highly integrated semiconductor device, and may also provide methods of manufacturing a semiconductor device capable of reducing or minimizing its manufacture cost.

Example embodiments have been disclosed herein, and although specific terms are employed, they are used and are to be interpreted in a generic and descriptive sense only and not for purpose of limitation. In some instances, as would be apparent to one of skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A method of manufacturing a semiconductor device, the method comprising:
forming an interlayer insulating layer on a substrate;
forming a plurality of contact holes penetrating the interlayer insulating layer, the plurality of contact holes arranged along a first direction and a second direction perpendicular to the first direction; and
forming contacts in the contact holes,
each contact hole being formed using a photo mask that is distinct from a photo mask used for forming a contact hole immediately adjacent to each contact hole in the first direction and distinct from a photo mask used for forming a contact hole immediately adjacent to each contact hole in the second direction, and
top surfaces of the contacts being at a same level from the substrate.

2. The method as claimed in claim 1, further comprising:
forming a plurality of active patterns extending in the first direction on the substrate;
forming a plurality of gate structures intersecting the active patterns and extending in the second direction; and
forming source/drain regions in the active patterns at both sides of each gate structure,
wherein the interlayer insulating layer covers the active patterns, the gate structures, and the source/drain regions, and
wherein the contact holes are arranged in the first direction with at least one of the gate structures therebetween and are arranged along one sidewall of each gate structure in the second direction.

3. The method as claimed in claim 2, wherein the contact holes overlap with the source/drain regions when viewed from a plan view.

4. The method as claimed in claim 3, wherein at least one of the contact holes overlaps with at least two source/drain regions that are spaced apart from each other in the second direction.

5. The method as claimed in claim 2, wherein the contacts are electrically connected to the source/drain regions.

6. The method as claimed in claim 5, wherein at least one of the contacts has a bar shape extending in the second direction and electrically connects at least two source/drain regions, which are spaced apart from each other in the second direction, to each other.

7. The method as claimed in claim 2, wherein:
the contact holes expose the source/drain regions, and
the contacts are in contact with the source/drain regions.

8. The method as claimed in claim 2, further comprising forming connecting conductive patterns, each of which connects the source/drain regions at each side of each gate structure to each other,
wherein the contact holes expose top surfaces of the connecting conductive patterns, and
wherein the contacts are electrically connected to the source/drain regions through the connecting conductive patterns.

9. The method as claimed in claim 1, wherein the top surfaces of the contacts are coplanar with a top surface of the interlayer insulating layer.

10. The method as claimed in claim 1, wherein forming the plurality of contact holes includes:
forming first contact holes using a first photo mask, the first contact holes penetrating the interlayer insulating layer;
forming a first mask layer filling the first contact holes on the interlayer insulating layer;
forming second contact holes using a second photo mask, the second contact holes penetrating the first mask layer and the interlayer insulating layer;
forming a second mask layer filling the second contact holes on the first mask layer; and
forming third contact holes using a third photo mask, the third contact holes penetrating the second mask layer, the first mask layer, and the interlayer insulating layer.

11. The method as claimed in claim 10, further comprising forming gate structures on the substrate, the gate structures extending in the second directions and arranged in the first direction,
wherein the interlayer insulating layer covers the gate structures,
wherein the first and second contact holes are alternately and repeatedly arranged in the first direction, and
wherein the first and second contact holes adjacent to each other in the first direction are spaced apart from each other with at least one of the gate structures therebetween.

12. The method as claimed in claim 11, wherein the first and second contact holes are alternately and repeatedly arranged in the second direction along one sidewall of at least one of the gate structures.

13. The method as claimed in claim 12, wherein:
each of the third contact holes is spaced apart from at least one of the first contact holes or at least one of the second contact holes with at least one of the gate structures therebetween, and
each of the third contact holes is between one of the first contact holes and one of the second contact holes that is adjacent to the one of the first contact holes in the second direction.

14. The method as claimed in claim 10, wherein:
two contact holes immediately adjacent to each other in the first direction are different two of the first, second, and third contact holes, and
two contact holes immediately adjacent to each other in the second direction are different two of the first, second, and third contact holes.

15. The method as claimed in claim 10, wherein:
each of the first contact holes has a first width in the first direction,
each of the second contact holes has a second width in the first direction,
each of the third contact holes has a third width in the first direction, and
the first width, the second width, and the third width are equal to each other.

16. A method of manufacturing a semiconductor device, the method comprising:
forming a plurality of active patterns extending in a first direction on a substrate;
forming a plurality of gate structures intersecting the active patterns and extending in a second direction intersecting the first direction;
forming source/drain regions in the active patterns at both sides of each gate structure;
forming an interlayer insulating layer covering the active patterns, the gate structures, and the source/drain regions on the substrate; and
forming a plurality of contact holes penetrating the interlayer insulating layer, the plurality of contact holes arranged along the first direction and the second direction,
the contact holes being arranged in the first direction with at least one of the gate structures therebetween and being arranged in the second direction along one sidewall of each gate structure, and
each contact hole being formed using a photo mask that is distinct from a photo mask used for forming a contact hole immediately adjacent to each contact hole in the first direction and distinct from a photo mask used for forming a contact hole immediately adjacent to each contact hole in the second direction.

17. The method as claimed in claim 16, wherein the contact holes overlap with the source/drain regions when viewed from a plan view.

18. The method as claimed in claim 16, further comprising forming contacts in the contact holes,
wherein top surfaces of the contacts are at a same level from the substrate.

19. The method as claimed in claim 18, wherein the contacts are electrically connected to the source/drain regions.

20. The method as claimed in claim 18, further comprising:
forming connecting conductive patterns each of which connects the source/drain regions at each side of each gate structure to each other,
wherein the contact holes expose top surfaces of the connecting conductive patterns, and
wherein the contacts are electrically connected to the source/drain regions through the connecting conductive patterns.
